(19) United States
(12) Patent Application Publication
(10) Pub. No.: US 2023/0084304 A1
(43) Pub. Date: Mar. 16, 2023

(54) APPARATUS FOR MEASURING SOC OF VEHICLE BATTERY AND METHOD THEREOF

(71) Applicants: Hyundai Motor Company, Seoul (KR); Kia Corporation, Seoul (KR)

(72) Inventor: Hee Gun YANG, Anyang-Si (KR)

(73) Assignees: Hyundai Motor Company, Seoul (KR); Kia Corporation, Seoul (KR)

(21) Appl. No.: 17/735,774

(22) Filed: May 3, 2022

(30) Foreign Application Priority Data
Sep. 16, 2021 (KR) 10-2021-0124150

(51) Int. Cl. B60L 58/12; G01R 31/382; H02J 7/00

(52) U.S. Cl. CPC B60L 58/12; G01R 31/382; H02J 7/0048

(57) ABSTRACT

An apparatus of measuring a state of charge (SOC) value of a vehicle battery is provided. The apparatus includes a first SOC value determination device that determines a first SOC value of a battery included in a vehicle, in response to that the vehicle is turned on, and a second SOC value measurement device that measures a second SOC value of the battery included in the vehicle, in response to that the vehicle is turned off. The first SOC value is a value determined based on the second SOC value.

### CROSS-REFERENCE TO RELATED APPLICATION

The present application claims priority to Korean Patent Application No. 10-2021-0124150, filed on Sep. 16, 2021, the entire contents of which is incorporated herein for all purposes by this reference.

### BACKGROUND OF THE INVENTION

### Field of the Invention

The present disclosure relates to an apparatus of measuring a state of charge (SOC) value of a vehicle battery and a method thereof.

### Description of Related art

An SOC value of a vehicle battery of a vehicle may be a value indicating a state of charge (SOC) value of the battery. In other words, the SOC value of the battery may be a numerical value represented as a percentage of the maximum amount of charge of the battery. For example, the SOC value of the battery may indicate 50%.

In general, a driver of the vehicle may identify an SOC value of the battery while driving the vehicle. The SOC value of the battery may be continuously changed by charging/discharging generated while the vehicle is traveling. Herein, because the amount of battery charging generated while driving is not fully delivered to the battery, according to a charging coefficient of the battery, it is impossible to display an accurate SOC value of the battery.

The information disclosed in this Background of the Invention section is only for enhancement of understanding of the general background of the invention and may not be taken as an acknowledgement or any form of suggestion that this information forms the prior art already known to a person skilled in the art.

### BRIEF SUMMARY

Various aspects of the present disclosure are directed to providing an apparatus or a method for determining a charging coefficient of a battery based on an SOC value measured in a battery stabilization state after a vehicle is turned off and correcting an SOC value displayed in a state where the vehicle is turned on to provide a more accurate SOC value of the battery.

The technical problems to be solved by the present disclosure are not limited to the aforementioned problems, and any other technical problems not mentioned herein will be clearly understood from the following description by those skilled in the art to which the present disclosure pertains.

According to an aspect of the present disclosure, an apparatus of measuring a state of charge (SOC) value of a battery may include a first SOC value determination device that determines a first SOC value of the battery included in a vehicle, in response to that the vehicle is turned on and a second SOC value measurement device that measures a second SOC value of the battery included in the vehicle, in response to that the vehicle is turned off. The first SOC value may be a value determined based on the second SOC value.

Furthermore, according to various exemplary embodiments of the present disclosure, the first SOC value may be determined based on a first value about charging of the battery, a second value about discharging of the battery, and a third value about a charging coefficient of the battery.

Furthermore, according to various exemplary embodiments of the present disclosure, the first value may be a value predicated based on an amount of current charging the battery. The second value may be a value predicated based on an amount of current discharged from the battery.

Furthermore, according to various exemplary embodiments of the present disclosure, the third value about the charging coefficient of the battery may be determined based on the value predicted based on the amount of the current charging the battery and an amount actually charged based on the amount of the current charging the battery.

Furthermore, according to various exemplary embodiments of the present disclosure, the third value about the charging coefficient of the battery may correspond to a value obtained by dividing the value indicating the amount actually charged based on the amount of the current charging the battery by the value predicted based on the amount of the current charging the battery.

Furthermore, according to various exemplary embodiments of the present disclosure, a difference value between the value predicted based on the amount of the current charging the battery and the value indicating the amount actually charged based on the amount of the current charging the battery may correspond to a difference value between the first SOC value and the second SOC value.

Furthermore, according to various exemplary embodiments of the present disclosure, a value obtained by subtracting the value indicating the amount actually charged based on the amount of the current charging the battery from the value predicted based on the amount of the current charging the battery may correspond to a value obtained by subtracting the second SOC value from the first SOC value.

Furthermore, according to various exemplary embodiments of the present disclosure, the first SOC value may be determined based on a value obtained by multiplying the first value about the charging of the battery by the third value about the charging coefficient of the battery and the second value about the discharging of the battery.

Furthermore, according to various exemplary embodiments of the present disclosure, the first SOC value may correspond to a value obtained by subtracting the second value about the discharging of the battery from the value obtained by multiplying the first value about the charging of the battery by the third value about the charging coefficient of the battery.

Furthermore, according to various exemplary embodiments of the present disclosure, the second SOC value measurement device may measure the second SOC value of the battery included in the vehicle, in response to that a predetermined time period elapses after the vehicle is turned off.

According to another aspect of the present disclosure, a method for measuring a state of charge (SOC) value of a battery may include determining a first SOC value of the battery included in a vehicle, in response to that the vehicle is turned on and measuring a second SOC value of the battery included in the vehicle, in response to that the vehicle is turned off. The first SOC value may be a value determined based on the second SOC value.

Furthermore, according to various exemplary embodiments of the present disclosure, the first SOC value may be determined based on a first value about charging of the battery, a second value about discharging of the battery, and a third value about a charging coefficient of the battery.

Furthermore, according to various exemplary embodiments of the present disclosure, the first value may be a value predicated based on an amount of current charging the battery. The second value may be a value predicated based on an amount of current discharged from the battery.

Furthermore, according to various exemplary embodiments of the present disclosure, the third value about the charging coefficient of the battery may be determined based on the value predicted based on the amount of the current charging the battery and an amount actually charged based on the amount of the current charging the battery.

Furthermore, according to various exemplary embodiments of the present disclosure, the third value about the charging coefficient of the battery may correspond to a value obtained by dividing the value indicating the amount actually charged based on the amount of the current charging the battery by the value predicted based on the amount of the current charging the battery.

Furthermore, according to various exemplary embodiments of the present disclosure, a difference value between the value predicted based on the amount of the current charging the battery and the value indicating the amount actually charged based on the amount of the current charging the battery may correspond to a difference value between the first SOC value and the second SOC value.

Furthermore, according to various exemplary embodiments of the present disclosure, a value obtained by subtracting the value indicating the amount actually charged based on the amount of the current charging the battery from the value predicted based on the amount of the current charging the battery may correspond to a value obtained by subtracting the second SOC value from the first SOC value.

Furthermore, according to various exemplary embodiments of the present disclosure, the first SOC value may be determined based on a value obtained by multiplying the first value about the charging of the battery by the third value about the charging coefficient of the battery and the second value about the discharging of the battery.

Furthermore, according to various exemplary embodiments of the present disclosure, the first SOC value may correspond to a value obtained by subtracting the second value about the discharging of the battery from the value obtained by multiplying the first value about the charging of the battery by the third value about the charging coefficient of the battery.

Furthermore, according to various exemplary embodiments of the present disclosure, the measuring of the second SOC value of the battery included in the vehicle may include measuring the second SOC value of the battery included in the vehicle, in response to that a predetermined time period elapses after the vehicle is turned off.

The methods and apparatuses of the present disclosure have other features and advantages which will be apparent from or are set forth in more detail in the accompanying drawings, which are incorporated herein, and the following Detailed Description, which together serve to explain certain principles of the present disclosure.

### BRIEF DESCRIPTION OF THE DRAWINGS

FIG. 1 illustrates an example of an apparatus of measuring an SOC value of a vehicle battery according to various exemplary embodiments;

FIG. 2 is a drawing illustrating an example of a process where a first SOC value is determined according to various exemplary embodiments;

FIG. 3 illustrates an example of a method for measuring an SOC value of a vehicle battery according to various exemplary embodiments; and

FIG. 4 illustrates an example of a method for measuring an SOC value of a vehicle battery according to various exemplary embodiments of the present disclosure.

It may be understood that the appended drawings are not necessarily to scale, presenting a somewhat simplified representation of various features illustrative of the basic principles of the present disclosure. The specific design features of the present disclosure as included herein, including, for example, specific dimensions, orientations, locations, and shapes will be determined in part by the particularly intended application and use environment.

In the figures, reference numbers refer to the same or equivalent parts of the present disclosure throughout the several figures of the drawing.

### DETAILED DESCRIPTION

Reference will now be made in detail to various embodiments of the present disclosure(s), examples of which are illustrated in the accompanying drawings and described below. While the present disclosure(s) will be described in conjunction with exemplary embodiments of the present disclosure, it will be understood that the present description is not intended to limit the present disclosure(s) to those exemplary embodiments of the present disclosure. On the other hand, the present disclosure(s) is/are intended to cover not only the exemplary embodiments of the present disclosure, but also various alternatives, modifications, equivalents and other embodiments, which may be included within the spirit and scope of the present disclosure as defined by the appended claims.

Hereinafter, various exemplary embodiments of the present disclosure will be described in detail with reference to the accompanying drawings. In adding the reference numerals to the components of each drawing, it should be noted that the identical component is designated by the identical numerals even when they are displayed on other drawings. Furthermore, in describing the exemplary embodiment of the present disclosure, a detailed description of well-known features or functions will be ruled out in order not to unnecessarily obscure the gist of the present disclosure.

In describing the components of the exemplary embodiment according to an exemplary embodiment of the present disclosure, terms such as first, second, “A”, “B”, (a), (b), and the like may be used. These terms are merely intended to distinguish one component from another component, and the terms do not limit the nature, sequence or order of the constituent components. Furthermore, unless otherwise defined, all terms used herein, including technical or scientific terms, have the same meanings as those generally understood by those skilled in the art to which the present disclosure pertains. Such terms as those defined in a generally used dictionary are to be interpreted as having meanings equal to the contextual meanings in the relevant field of art, and are not to be interpreted as having ideal or excessively formal meanings unless clearly defined as having such in the present application.

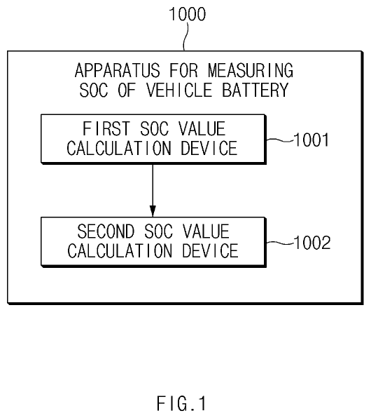

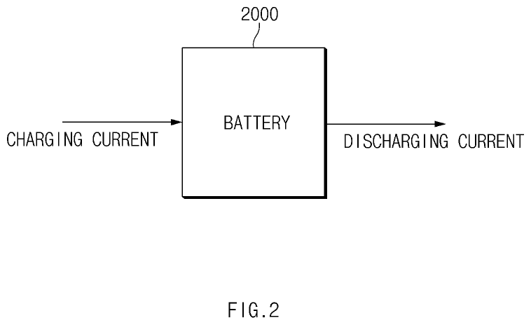

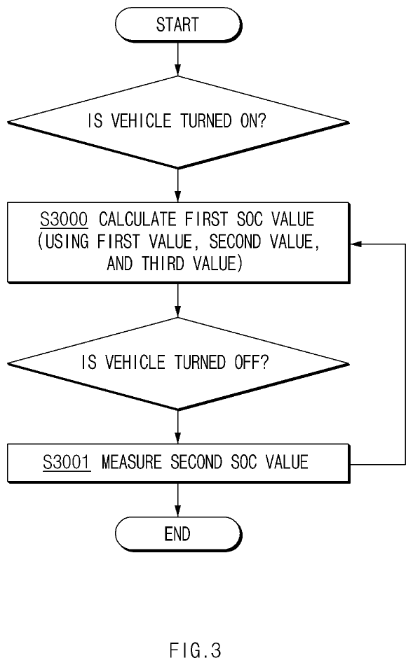

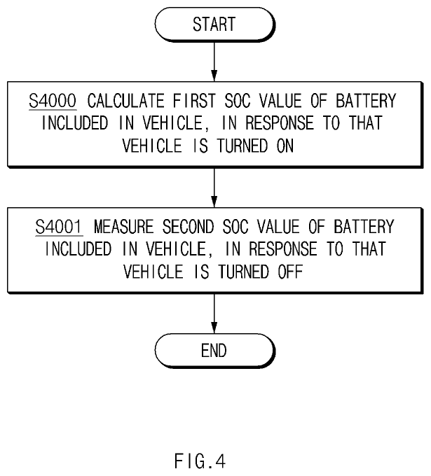

Hereinafter, various embodiments of the present disclosure will be described in detail with reference to FIG. 1, FIG. 2, FIG. 3, and FIG. 4.

FIG. 1 illustrates an example of an apparatus of measuring a state of charge (SOC) value of a vehicle battery according to various exemplary embodiments of the present disclosure.

The drawing illustrates an example of an apparatus 1000 for measuring an SOC of a vehicle battery (or an apparatus 1000) according to various exemplary embodiments of the present disclosure.

A vehicle according to various exemplary embodiments of the present disclosure may include at least one of an electric vehicle (EV), a hybrid electric vehicle (HEV), and/or a plug-in hybrid electric vehicle (PHEV). In other words, the vehicle according to various exemplary embodiments of the present disclosure may be driven based on a battery included in the vehicle.

An SOC value of the battery according to various exemplary embodiments of the present disclosure may be a value indicating a state of charge of the battery. In other words, the SOC value of the battery may be a numerical value represented as a percentage of the maximum amount of charge of the battery. For example, the SOC value of the battery may indicate 50%.

In general, a driver of the vehicle may identify an SOC value of the battery while driving the vehicle. The SOC value of the battery may be continuously changed by charging/discharging generated while the vehicle is traveling. Herein, because the amount of battery charging generated while driving is not fully delivered to the battery, according to a charging coefficient of the battery, it is impossible to display an accurate SOC value of the battery.

The apparatus 1000 according to various exemplary embodiments of the present disclosure may determine a charging coefficient of the battery based on an SOC value measured in a battery stabilization state when the vehicle is turned off, may correct an SOC value displayed in a state where the vehicle is turned on, thus providing a more accurate SOC value of the battery.

The apparatus 1000 according to various exemplary embodiments of the present disclosure may include a first SOC value determination device 1001 and/or a second SOC value determination device 1002. The apparatus 1000 according to various exemplary embodiments of the present disclosure may further include one or more elements which are not shown in the drawing. The apparatus 1000 according to various exemplary embodiments of the present disclosure may be located inside or outside the vehicle.

The first SOC value determination device 1001 according to various exemplary embodiments of the present disclosure may determine a first SOC value of the battery included in the vehicle, in response to that the vehicle is turned on.

The first SOC value according to various exemplary embodiments of the present disclosure may be a battery SOC value by charging/discharging of the battery, which is generated in a state where the vehicle is turned on. For example, the first SOC value may be a battery SOC value based on discharging of the battery, which is generated while the vehicle is traveling, and charging of the battery according to regenerative braking.

Furthermore, the first SOC value according to various exemplary embodiments of the present disclosure may be an SOC value predicted based on the above-mentioned charging/discharging. The amount of charging based on a charging current injected into the battery to charge the battery in a state where the vehicle is turned on may also include the amount of charging lost by heat loss or the like. In other words, the first SOC value may indicate a value different from an actual SOC value of the battery.

The first SOC value according to various exemplary embodiments of the present disclosure may be an SOC value determined based on the amount of charging/discharging accumulated from a state where the vehicle is turned on to a state where the vehicle is turned off.

The second SOC value determination device 1002 according to various exemplary embodiments of the present disclosure may determine a second SOC value of the battery included in the vehicle, in response to that the vehicle is turned off.

The second SOC value according to various exemplary embodiments of the present disclosure may be an actual SOC value of the battery, which is measured when the battery arrives at a stabilization state after the vehicle is turned off. Thus, the second SOC value may be an SOC value measured in response to that a predetermined time period elapses after the vehicle is turned off. For example, the second SOC value may be an SOC value of the battery, which is measured when three hours elapse after the vehicle is turned off.

The apparatus 1000 according to various exemplary embodiments of the present disclosure may determine a charging coefficient of the battery based on the first SOC value and the second SOC value. The charging coefficient of the battery may be a value indicating the ratio of the amount of charging by a charging current to the amount of charging which is actually charged.

The first SOC value according to various exemplary embodiments of the present disclosure may be determined based on the above-mentioned charging coefficient. In other words, the first SOC value may be a value determined based on the second SOC value.

The apparatus 1000 according to various exemplary embodiments of the present disclosure may measure an SOC value again in a stabilization state of the battery, by the method described with reference to the drawing, to obtain a charging coefficient of the battery. Furthermore, the apparatus 1000 may determine a predicted value of an SOC value displayed in a state where the vehicle is turned on, based on the charging coefficient of the battery, and may provide a user (or a driver) with a more accurate SOC value.

FIG. 2 is a drawing illustrating an example of a process where a first SOC value is determined according to various exemplary embodiments of the present disclosure.

The drawing illustrates an example of a process where the first SOC value (e.g., a first SOC value described above with reference to FIG. 1) is determined according to various exemplary embodiments of the present disclosure.

As described above with reference to FIG. 1, the first SOC value may be an SOC value predicted according to charging/discharging of a battery 2000, from a state where the vehicle is turned on to a state where the vehicle is turned off.

The above-mentioned charging and/or discharging of the battery 2000 may be based on a charging current charging the battery 2000 and/or a discharging current discharged from the battery 2000. In other words, the charging current may be current for charging the battery 2000, and the discharging current may be current discharged from the battery 2000.

The first SOC value according to various exemplary embodiments of the present disclosure may be determined based on a first value about charging of the battery 2000, a second value about discharging of the battery 2000, and a third value about a charging coefficient of the battery 2000.

The first value according to various exemplary embodiments of the present disclosure may indicate a value predicted based on the amount of current charging the battery 2000. The current charging the battery 2000 may be the above-mentioned charging current. The first value may be an SOC value of the battery 2000, which is predicted to be charged, depending on a charging current value measured by a detector which is embedded in the battery 2000 or is located outside the battery 2000.

The second value according to various exemplary embodiments of the present disclosure may be a value predicted based on current discharged from the battery 2000. The current discharged from the battery 2000 may be the above-mentioned discharging current. The second value may be an SOC value of the battery 2000, which is predicted to be discharged, depending on a discharging current value measured by a detector which is embedded in the battery 2000 or is located outside the battery 2000.

As described above with reference to FIG. 1, the first value may be the concept including an SOC value of the battery 2000, which is lost due to heat loss or the like. In other words, the first value may be a value greater than an SOC value actually charged in the battery 2000 according to the charging current. On the other hand, the second value may be the same as an SOC value actually discharged from the battery 2000 according to the discharging current.

The third value about the charging coefficient according to various exemplary embodiments of the present disclosure may be determined based on a value predicted based on the amount of current charging the battery 2000 and a value indicating an amount actually charged based on the amount of current charging the battery 2000. The value predicted based on the amount of current charging the battery 2000 may indicate the above-mentioned first value. The amount actually charged based on the amount of current charging the battery 2000 may indicate an SOC value actually charged in the battery 2000 according to the above-mentioned charging current.

As described above with reference to FIG. 1, the charging coefficient may be a value indicating the ratio of the amount of charging by a charging current to the amount of charging which is actually charged. In other words, the charging coefficient may indicate the ratio between the above-mentioned two values. For example, the third value about the charging coefficient of the battery 2000 may correspond to a value obtained by dividing the value indicating the amount actually charged based on the amount of current charging the battery 2000 by the value predicted based on the amount of current charging the battery 2000.

As described above with reference to FIG. 1, the second SOC value according to various exemplary embodiments of the present disclosure may be an actual SOC value of the battery 2000, which is measured when the battery 2000 arrives at a stabilization state after the vehicle is turned off. When the battery 2000 arrives at the stabilization state after the vehicle is turned off, there may be no a charging current/discharging current flowing into the battery 2000 or flowing out of the battery 2000.

An apparatus 1000 according to various exemplary embodiments of the present disclosure may measure the second SOC value which is an actual SOC value of the battery 2000 in a battery stabilization state. The second SOC value which is the actual SOC value of the battery 2000 may be a value in which an SOC value lost due to the above-mentioned heat loss or the like is also reflected. In other words, the apparatus 1000 may compare the first SOC value with the second SOC value to know the above-mentioned lost SOC value.

In other words, a difference value between the value predicted based on the amount of current charging the battery 2000 and the value indicating the amount actually charged based on the amount of current charging the battery 2000 may correspond to a difference value between the first SOC value and the second SOC value. For example, a value obtained by subtracting the value indicating the amount actually charged based on the amount of current charging the battery 2000 from the value predicted based on the amount of current charging the battery 2000 may correspond to a value obtained by subtracting the second SOC value from the first SOC value.

The apparatus 1000 according to various exemplary embodiments of the present disclosure may determine the charging coefficient by the above-mentioned method and may use the charging coefficient in determining the first SOC value which is a predicted value of an SOC value of the battery 2000 in a state where the vehicle is turned on subsequently. In other words, the apparatus 1000 may multiply the first value about the charging of the battery 2000 by the third value about the charging coefficient of the battery 2000 to more accurately predict an SOC value of the battery 2000, which is actually charged according to the charging current.

In other words, the first SOC value according to various exemplary embodiments of the present disclosure may be determined based on a value obtained by multiplying the first value about the charging of the battery 2000 by the third value about the charging coefficient of the battery 2000 and the second value about the discharging of the battery 2000. For example, the first SOC value may correspond to a value obtained by subtracting the second value about the discharging of the battery 2000 from the value obtained by multiplying the first value about the charging of the battery 2000 by the third value about the charging coefficient of the battery 2000.

The apparatus 1000 according to various exemplary embodiments of the present disclosure may measure an SOC value again in a stabilization state of the battery 2000, by the method described with reference to the drawing, to obtain a charging coefficient of the battery 2000. Furthermore, the apparatus 1000 may determine a predicted value of an SOC value displayed in a state where the vehicle is turned on, based on the charging coefficient of the battery 2000, and may provide a user (or a driver) with a more accurate SOC value.

FIG. 3 illustrates an example of a method for measuring an SOC value of a vehicle battery according to various exemplary embodiments of the present disclosure.

The drawing illustrates an example of a method for measuring an SOC value of a vehicle battery (or a method) according to various exemplary embodiments of the present disclosure.

An apparatus 1000 described above with reference to FIG. 1 and FIG. 2 may perform the method described in the drawing.

In S3000, the apparatus 1000 (e.g., a first SOC value determination device 1001 of FIG. 1) according to various exemplary embodiments of the present disclosure may determine a first SOC value of a battery included in a vehicle, in response to that the vehicle is turned on.

As described above with reference to FIG. 1 and FIG. 2, the first SOC value according to various exemplary embodiments of the present disclosure may be determined based on a first value about charging of the battery, a second value about discharging of the battery, and a third value about a charging coefficient of the battery. A detailed description of the first to third values may be the same or similar to that described above with reference to FIGS. 1 to 2.

In other words, the apparatus 1000 may determine a prediction value of a battery SOC value at a time when the vehicle is turned off, based on charging/discharging of the battery from a state where the vehicle is turned on to a state where the vehicle is turned off.

Herein, as described above with reference to FIG. 1 and FIG. 2, the amount of charge of the battery based on the charging current may include a battery SOC value lost by heat loss or the like. Thus, the above-mentioned predicted value (e.g., the first SOC value) of the battery SOC value may be different from an actual SOC value of the battery.

In S3001, the apparatus 1000 (e.g., a second SOC value determination device 1002 of FIG. 1) according to various exemplary embodiments of the present disclosure may determine a second SOC value of the battery included in the vehicle, in response to that the vehicle is turned off. In other words, the apparatus 1000 may measure an actual SOC value of the battery. In other words, the second SOC value determination device 1002 according to various exemplary embodiments of the present disclosure may measure the second SOC value of the battery included in the vehicle, in response to that a predetermined time period elapses after the vehicle is turned off.

The apparatus 1000 according to various exemplary embodiments of the present disclosure may compare the first SOC value which is the predicted value of the battery SOC value with the second SOC value which is the actual SOC value of the battery to determine a charging coefficient of the battery. A detailed description of the method for determining the charging coefficient may be the same or similar to that described above with reference to FIG. 2.

The apparatus 1000 according to various exemplary embodiments of the present disclosure may use the above-mentioned charging coefficient in determining the first SOC value determined in a state where the vehicle is turned on subsequently. In other words, the first SOC value may be a value determined based on the second SOC value. A detailed description of the method for using the charging coefficient in determining the first SOC value in the apparatus 1000 may be the same or similar to that described above with reference to FIG. 2.

The apparatus 1000 according to various exemplary embodiments of the present disclosure may measure an SOC value again in a stabilization state of the battery, by the method described with reference to the drawing, to obtain a charging coefficient of the battery. Furthermore, the apparatus 1000 may determine a predicted value of an SOC value displayed in a state where the vehicle is turned on, based on the charging coefficient of the battery, and may provide a user (or a driver) with a more accurate SOC value.

FIG. 4 illustrates an example of a method for measuring an SOC value of a vehicle battery according to various exemplary embodiments of the present disclosure.

The drawing is a flowchart illustrating an example of a method for measuring an SOC value of a vehicle battery (e.g., a method described above with reference to FIG. 3) according to various exemplary embodiments of the present disclosure.

An apparatus 1000 described above with reference to FIG. 1, FIG. 2, and FIG. 3 may perform the method described in the drawing.

The method according to various exemplary embodiments of the present disclosure may include determining (S4000) a first SOC value of a battery included in a vehicle, in response to that the vehicle is turned on, and measuring (S4001) a second SOC value of the battery included in the vehicle, in response to that the vehicle is turned off. The first SOC value according to various exemplary embodiments of the present disclosure may be a value determined based on the second SOC value.

A detailed description of the first SOC value and the second SOC value according to various exemplary embodiments of the present disclosure may be the same or similar to that described above with reference to FIG. 1, FIG. 2, and FIG. 3.

The first SOC value according to various exemplary embodiments of the present disclosure may be determined based on a first value about charging of the battery, a second value about discharging of the battery, and a third value about a charging coefficient of the battery. A detailed description of the first to third values may be the same or similar to that described above with reference to FIG. 1, FIG. 2, and FIG. 3.

The first value according to various exemplary embodiments of the present disclosure may indicate a value predicted based on the amount of current charging the battery. The second value according to various exemplary embodiments of the present disclosure may indicate a value predicted based on the amount of current discharged from the battery.

The third value about the charging coefficient according to various exemplary embodiments of the present disclosure may be determined based on a value predicted based on the amount of current charging the battery and a value indicating an amount actually charged based on the amount of current charging the battery. The third value about the charging coefficient of the battery according to various exemplary embodiments of the present disclosure may correspond to a value obtained by dividing the value indicating the amount actually charged based on the amount of current charging the battery by the value predicted based on the amount of current charging the battery.

A detailed description of the value predicted based on the amount of current charging the battery and the value indicating the amount actually charged based on the amount of current charging the battery may be the same or similar to that described above with reference to FIG. 2.

According to various exemplary embodiments of the present disclosure, a difference value between the value predicted based on the amount of current charging the battery and the value indicating the amount actually charged based on the amount of current charging the battery may correspond to a difference value between the first SOC value and the second SOC value. According to various exemplary embodiments of the present disclosure, a value obtained by subtracting the value indicating the amount actually charged based on the amount of current charging the battery from the value predicted based on the amount of current charging the battery may correspond to a value obtained by subtracting the second SOC value from the first SOC value.

The first SOC value according to various exemplary embodiments of the present disclosure may be determined based on a value obtained by multiplying the first value about the charging of the battery by the third value about the charging coefficient of the battery and the second value about the discharging of the battery. The first SOC value according to various exemplary embodiments of the present disclosure may correspond to a value obtained by subtracting the second value about the discharging of the battery from the value obtained by multiplying the first value about the charging of the battery by the third value about the charging coefficient of the battery.

According to various exemplary embodiments of the present disclosure, 54001 may include measuring the second SOC value of the battery included in the vehicle, in response to that a predetermined time period elapses after the vehicle is turned off.

The apparatus 1000 according to various exemplary embodiments of the present disclosure may measure an SOC value again in a stabilization state of the battery, by the method described with reference to the drawing, to obtain a charging coefficient of the battery. Furthermore, the apparatus 1000 may determine a predicted value of an SOC value displayed in a state where the vehicle is turned on, based on the charging coefficient of the battery, and may provide a user (or a driver) with a more accurate SOC value.

Embodiments may determine a charging coefficient of the battery based on an SOC value measured in a battery stabilization state after the vehicle is turned off and may correct an SOC value displayed in a state where the vehicle is turned on, thus providing a more accurate SOC value of the battery.

Furthermore, various effects ascertained directly or indirectly through the present disclosure may be provided.

Furthermore, the apparatus 1000 may be implemented by a hardware device including a memory and a processor configured to execute one or more steps interpreted as an algorithm structure. The memory stores algorithm steps, and the processor executes the algorithm steps to perform one or more processes of a method in accordance with various exemplary embodiments of the present disclosure. The control device according to exemplary embodiments of the present disclosure may be implemented through a nonvolatile memory configured to store algorithms for controlling operation of various components of a vehicle or data about software commands for executing the algorithms, and a processor configured to perform operation to be described above using the data stored in the memory. The memory and the processor may be individual chips.

Alternatively, the memory and the processor may be integrated in a single chip. The processor may be implemented as one or more processors. The processor may include various logic circuits and operation circuits, may process data according to a program provided from the memory, and may generate a control signal according to the processing result.

In various exemplary embodiments of the present disclosure, the apparatus 1000 may be implemented in a form of hardware or software, or may be implemented in a combination of hardware and software.

For convenience in explanation and accurate definition in the appended claims, the terms “upper”, “lower”, “inner”, “outer”, “up”, “down”, “upwards”, “downwards”, “front”, “rear”, “back”, “inside”, “outside”, “inwardly”, “outwardly”, “interior”, “exterior”, “internal”, “external”, “forwards”, and “backwards” are used to describe features of the exemplary embodiments with reference to the positions of such features as displayed in the figures. It will be further understood that the term “connect” or its derivatives refer both to direct and indirect connection.

Furthermore, the term of “fixedly connected” signifies that fixedly connected members always rotate at a same speed. Furthermore, the term of “selectively connectable” signifies “selectively connectable members rotate separately when the selectively connectable members are not engaged to each other, rotate at a same speed when the selectively connectable members are engaged to each other, and are stationary when at least one of the selectively connectable members is a stationary member and remaining selectively connectable members are engaged to the stationary member”.

The foregoing descriptions of predetermined exemplary embodiments of the present disclosure have been presented for purposes of illustration and description. They are not intended to be exhaustive or to limit the present disclosure to the precise forms disclosed, and obviously many modifications and variations are possible in light of the above teachings. The exemplary embodiments were chosen and described to explain predetermined principles of the present disclosure and their practical application, to enable others skilled in the art to make and utilize various exemplary embodiments of the present disclosure, as well as various alternatives and modifications thereof. It is intended that the scope of the present disclosure be defined by the Claims appended hereto and their equivalents.

What is claimed is:

1. An apparatus of measuring a state of charge (SOC) value of a battery, the apparatus comprising:
a first SOC value determination device configured to determine a first SOC value of the battery included in a vehicle, in response to that the vehicle is turned on; and
a second SOC value measurement device configured to measure a second SOC value of the battery included in the vehicle, in response to that the vehicle is turned off,
wherein the first SOC value is a value determined based on the second SOC value.

2. The apparatus of claim 1, wherein the first SOC value is determined based on a first value about charging of the battery, a second value about discharging of the battery, and a third value about a charging coefficient of the battery.

3. The apparatus of claim 2,
wherein the first value is a value predicated according to an amount of current charging the battery, and
wherein the second value is a value predicated according to an amount of current discharged from the battery.

4. The apparatus of claim 3, wherein the third value about the charging coefficient of the battery is determined based on the value predicted according to the amount of the current charging the battery and an amount actually charged based on the amount of the current charging the battery.

5. The apparatus of claim 4, wherein the third value about the charging coefficient of the battery corresponds to a value obtained by dividing the value indicating the amount actually charged based on the amount of the current charging the battery by the value predicted according to the amount of the current charging the battery.

6. The apparatus of claim 4, wherein a difference value between the value predicted according to the amount of the current charging the battery and the value indicating the amount actually charged based on the amount of the current charging the battery corresponds to a difference value between the first SOC value and the second SOC value.

7. The apparatus of claim 6, wherein a value obtained by subtracting the value indicating the amount actually charged based on the amount of the current charging the battery from the value predicted according to the amount of the current charging the battery corresponds to a value obtained by subtracting the second SOC value from the first SOC value.

8. The apparatus of claim 5, wherein the first SOC value is determined based on a value obtained by multiplying the first value about the charging of the battery by the third value about the charging coefficient of the battery and the second value about the discharging of the battery.

9. The apparatus of claim 8, wherein the first SOC value corresponds to a value obtained by subtracting the second value about the discharging of the battery from the value obtained by multiplying the first value about the charging of the battery by the third value about the charging coefficient of the battery.

10. The apparatus of claim 1, wherein the second SOC value measurement device is configured to measure the second SOC value of the battery included in the vehicle, in response to that a predetermined time period elapses after the vehicle is turned off.

11. A method for measuring a state of charge (SOC) value of a battery, the method comprising:
determining a first SOC value of the battery included in a vehicle, in response to that the vehicle is turned on; and
measuring a second SOC value of the battery included in the vehicle, in response to that the vehicle is turned off,
wherein the first SOC value is a value determined based on the second SOC value.

12. The method of claim 11, wherein the first SOC value is determined based on a first value about charging of the battery, a second value about discharging of the battery, and a third value about a charging coefficient of the battery.

13. The method of claim 12,
wherein the first value is a value predicated according to an amount of current charging the battery, and
wherein the second value is a value predicated according to an amount of current discharged from the battery.

14. The method of claim 13, wherein the third value about the charging coefficient of the battery is determined based on the value predicted according to the amount of the current charging the battery and an amount actually charged based on the amount of the current charging the battery.

15. The method of claim 14, wherein the third value about the charging coefficient of the battery corresponds to a value obtained by dividing the value indicating the amount actually charged based on the amount of the current charging the battery by the value predicted according to the amount of the current charging the battery.

16. The method of claim 14, wherein a difference value between the value predicted according to the amount of the current charging the battery and the value indicating the amount actually charged based on the amount of the current charging the battery corresponds to a difference value between the first SOC value and the second SOC value.

17. The method of claim 16, wherein a value obtained by subtracting the value indicating the amount actually charged based on the amount of the current charging the battery from the value predicted according to the amount of the current charging the battery corresponds to a value obtained by subtracting the second SOC value from the first SOC value.

18. The method of claim 15, wherein the first SOC value is determined based on a value obtained by multiplying the first value about the charging of the battery by the third value about the charging coefficient of the battery and the second value about the discharging of the battery.

19. The method of claim 18, wherein the first SOC value corresponds to a value obtained by subtracting the second value about the discharging of the battery from the value obtained by multiplying the first value about the charging of the battery by the third value about the charging coefficient of the battery.

20. The method of claim 11, wherein the measuring of the second SOC value of the battery included in the vehicle includes:
measuring the second SOC value of the battery included in the vehicle, in response to that a predetermined time period elapses after the vehicle is turned off.
